(19) United States
(12) Patent Application Publication
(10) Pub. No.: US 2013/0182816 A1
(43) Pub. Date: Jul. 18, 2013

(54) CLOCK DIVIDER CIRCUIT

(71) Applicant: Michael R. Skripek, Scotts Valley, CA (US)

(72) Inventor: Michael R. Skripek, Scotts Valley, CA (US)

(73) Assignee: Cisco Technology, Inc., San Jose, CA (US)

(21) Appl. No.: 13/366,016

(22) Filed: Feb. 3, 2012

Related U.S. Application Data
(63) Continuation-in-part of application No. 13/353,046, filed on Jan. 18, 2012, now abandoned.

(51) Int. Cl. H03K 23/00

(52) U.S. Cl. 377/47

(57) ABSTRACT

In one embodiment, a clock divider circuit preserves characteristics of both a rising edge and a falling edge of a source clock. The clock divider circuit may include a counter, a flip-flop, and an output. The counter is configured to divide a source clock signal into a divided clock signal. The flip-flop is configured to receive the divided clock signal and an inverse of the source clock signal to trigger the flip-flop. The output includes a logic gate configured to output a final clock signal based on a logical union of an output of the flip-flop and the divided clock signal. The final clock signal includes the jitter from the falling edge of the source clock and the jitter from the rising edge of the source clock.

### CROSS-REFERENCE TO RELATED APPLICATIONS

This application is a continuation-in-part of U.S. patent application Ser. No. 13/353,046, filed Jan. 18, 2012, which is hereby incorporated by reference in its entirety.

### FIELD

The present disclosure relates to a clock divider circuit and detection of jitter on the output of the clock divider circuit.

### BACKGROUND

In some applications, high frequency clock signals cannot be easily observed. A counter may be used to slow down the clock signal. The output of the counter increments after a certain number of clock cycles, effectively producing a slowed down version of the clock signal. The slower clock signal may be observed and analyzed. One of the attributes of the clock signal that is observed and analyzed is jitter.

Jitter describes the deviation of a periodic signal from perfect periodic operation. Jitter may be the deviation in frequency of successive cycles of the periodic signal, the deviation in amplitude of successive cycles of the periodic signal, or the deviation of phase of successive cycles of the periodic signal. Jitter may be caused by an external stimulus to the clock or another circuit such as temperature, voltage variation, and manufacturing related variables. Due to the operation of conventional counters, jitter is measured on only a single edge of the clock signal.

### BRIEF DESCRIPTION OF THE DRAWINGS

FIG. 1 illustrates a system for testing an integrated circuit.

FIG. 2 illustrates a clock divider circuit of FIG. 1.

FIG. 3 illustrates another implementation of the clock divider circuit of FIG. 1.

FIG. 4 illustrates another implementation of the clock divider circuit of FIG. 1.

FIG. 5 illustrates an example of the test equipment of FIG. 1.

FIG. 6 illustrates an example flow chart for generating a clock that can be analyzed for jitter on both output edges.

### DETAILED DESCRIPTION

### Overview

In one aspect, a method includes converting a source clock signal into a divided clock signal using a counter. The divided clock signal, which preserves jitter from a first edge of the source clock signal, is fed to an input of a two-state sequential logic device. An inverse of the source clock signal, which preserves jitter from a second edge of the source clock signal, triggers the two-state sequential logic device. A logical union or intersection of an output of the two-state sequential logic device and the divided clock signal as a final clock signal is output such that the final clock signal includes the jitter from a falling edge of the source clock signal and the jitter from a rising edge of the source clock signal.

In a second aspect, an apparatus includes a counter, a flip-flop, and a logic gate. The counter is configured to divide a source clock signal into a divided clock signal, wherein a frequency of the divided clock signal is lower than a frequency of the source clock signal. The flip-flop is configured to generate an output based on the divided clock signal and an inverse of the source clock signal. The logic gate is configured to generate a final clock signal based on a logical union of the output of the flip-flop and the divided clock signal. The final clock signal includes characteristics of a first edge of the source clock signal and characteristics of a second edge of the source clock signal.

In a third aspect, a computer readable medium includes instructions to divide a source clock signal into a divided clock signal using a ring counter, wherein a frequency of the divided clock signal is lower than a frequency of the source clock signal, feed the divided clock signal to an input of a flip-flop, wherein the divided clock signal preserves jitter from a rising edge of the source clock, feed an inverse of the source clock signal to trigger the flip-flop, wherein the inverse of the source clock signal preserves jitter from a falling edge of the source clock signal, and output a logical union of an output of the flip-flop and the divided clock signal as a final clock signal, wherein the final clock signal includes the jitter from the falling edge of the source clock signal and the jitter from the rising edge of the source clock signal.

### Example EMBODIMENTS

Oscilloscopes and other testing equipment are limited by capabilities to handle high frequency signals. In order to view and analyze high frequency signals on such limited equipment, a counter may be used to slow down the high frequency signals. The counter preserves characteristics of one edge of the high frequency signal. However, the characteristics of the other edge of the high frequency signal are lost. The following embodiments preserve characteristics of both edges of the high frequency signal.

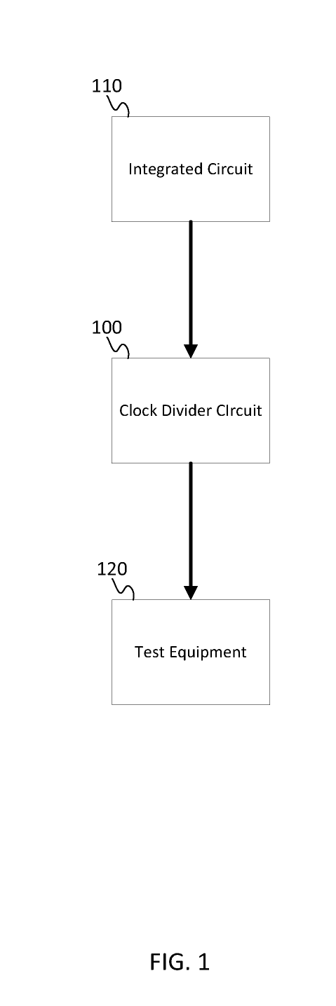

FIG. 1 illustrates an example of a system for testing an integrated circuit. The system includes an integrated circuit 110, a clock divider circuit 100, and test equipment 120. The system analyzes both edges of a clock signal generated at the integrated circuit 110.

The integrated circuit 110 includes a clock signal. The clock signal may be generated from an oscillator such as a crystal oscillator. The clock signal may have any frequency. Example frequencies include 100 MHz, 1 GHz, and 10 GHz. The integrated circuit 110 may be a programmable integrated circuit such as application specific integrated circuit (ASIC) or a field programmable gate array (FPGA). The integrated circuit 110 may include a microprocessor that operates any of a variety of electronic devices such as a computer, a cellular phone, a television, or a network device such as a router, a switch, a hub, a server, or a bridge.

The integrated circuit 110 may include phase lock loop circuitry. The phase lock loop circuitry includes a variable frequency oscillator and a phase detector. The phase lock loop circuitry receives a reference frequency and adjusts the variable frequency oscillator to match the phase of the reference frequency. The phase lock loop circuitry may also be configured to multiply the reference frequency to produce a final clock that can be a different speed from the input reference. As an example, a 125 MHz reference frequency may be used to create a 625 MHz on-chip clock.

The test equipment 120 is configured to analyze, measure, or view the output of the clock divider circuit 100. The test equipment 120 may include an oscilloscope such as a digital sampling oscilloscope, a digital storage oscilloscope, or a digital phosphor oscilloscope. The highest frequency that the oscilloscope can display may be limited by the sampling rate of the oscilloscope. In some applications the sampling rate is at least twice the frequency of the output of the clock divider circuit 100.

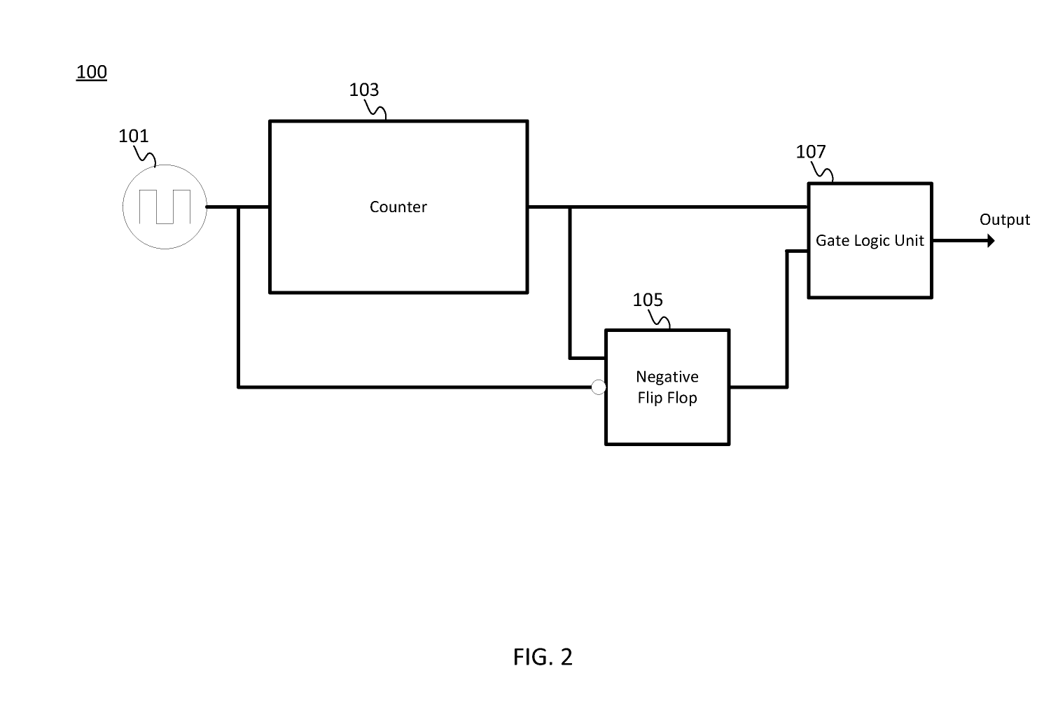

FIG. 2 illustrates an example of the clock divider circuit 100 of FIG. 1. The clock divider circuit 100 includes a counter 103, a negative flip-flop 105, and a gate logic unit 107. The negative flip-flop 105 is an opposite clock edge delay element because the clock input is inverted, triggering the negative flip-flop 105 on the falling edge of the source clock signal 101. Alternatively, in addition to a negative flip-flop, any other type of multiple-state sequential logic device may be used, such as a two-state sequential logic device, which includes all types of latches and flip-flops. The counter 103 may be any device capable of detecting edges of pulses, such as a user selectable clock edge element or a first clock edge element.

The clock divider circuit 100 receives the source clock signal 101 from the integrated circuit 110. The counter 103 converts a source clock signal into a divided clock signal. The divided clock signal has a lower frequency than the source clock signal 101 by a factor of N, where N is a multiple of two (e.g., 2, 4, 6, 8, etc.). Because the divided clock signal is driven by the rising edge of the source clock signal 101, the divided clock signal preserves jitter from the rising edge of the source clock signal 101. The clock divider circuit 100 feeds the divided clock signal to an input of the flip-flop 105. The clock divider circuit 100 feeds an inverse of the source clock signal 101 to trigger the flip-flop 105. The inverse of the source clock signal 101 preserves jitter from the falling edge of the source clock signal 101.

The counter 103 could alternatively be configured such that N is any integer value. Further, the counter 103 could be a fractional counter, where N is equal to any half-integer value (e.g., 1.5, 2.0, 2.5, etc.). However, additional logic may be required in the counter 103 in fractional counters if flip-flops or latches in the counter 103 operate on different clock edges.

The clock divider circuit 100 communicates the output of the flip-flop 105 and the divided clock signal. The gate logic unit 107 outputs the logical union of the output of the flip-flop 105 and the divided clock signal as a final clock signal. The final clock signal includes the jitter from the falling edge of the source clock signal 101 and the jitter from the rising edge of the source clock signal 101. The gate logic unit 107 may include an oring logic capability, such as an OR gate. The falling edge of the final clock signal includes the jitter of the falling edge of the source clock signal 101, and the rising edge of the final clock signal includes the jitter of the rising edge of the source clock signal 101.

Alternatively, the final clock signal may be generated using an anding logic capability, such as an AND gate, as the gate logic unit 107. The AND gate provides an intersection of the output of the two-state sequential logic device and the divided clock signal as a final clock signal. In this case, the rising edge of the final clock signal includes the jitter of the falling edge of the source clock signal 101, and the falling edge of the final clock signal includes the jitter of the rising edge of the source clock signal 101. In other implementations, the gate logic unit 107 may include a combination of logical gates to generate the final clock signal. The gate logic unit 107 may include one or more XOR gates, AND gates, OR gates, or any Boolean derivatives.

The output of the clock divider circuit 100 is sent to the test equipment 120. The test equipment analyzes the jitter from the falling edge of the source clock signal 101 and the jitter from the rising edge of the source clock signal 101. In one example, the test equipment 120 includes a display that graphically illustrates an image of the final clock signal. The test equipment may output a textual display of the jitter from the falling edge of the source clock signal 101 and/or the jitter from the rising edge of the source clock signal 101.

The jitter may be measured in a variety of units such as frequency units or time units. For example, when jitter is calculated as the deviation in frequency between successive pulses, the jitter is measured in frequency units (Hz, MHz, KHz, etc.). The jitter may alternately be measured in percentage change in frequency from one pulse to the next pulse. As another example, when jitter is calculated as the change in timing of the edge of a pulse, the jitter may be measured in time units (seconds, picoseconds, microseconds, nanoseconds, etc.). An example timing jitter is 350 picoseconds. Alternatively, jitter may be measured in amplitude of the signal (e.g., root mean squared or peak-to-peak displacement) or in terms of spectral density or frequency content.

In one example, the test equipment 120 compares the jitter from the falling edge of the source clock signal 101 or the jitter from the rising edge of the source clock signal 101 to a threshold level. The threshold level may be a predetermined number selected by the user. Example threshold levels include 100 KHz and 1 MHz for frequency units of jitter and 100 picoseconds or 100 nanoseconds for time units of jitter. The threshold level may be set as a percentage of the frequency of the source clock signal 101. The test equipment 120 generates an error message if the jitter from the falling edge of the source clock or the jitter from the rising edge of the source clock exceeds the threshold. The threshold may be programmable or determined based on characteristics of the source clock signal 101.

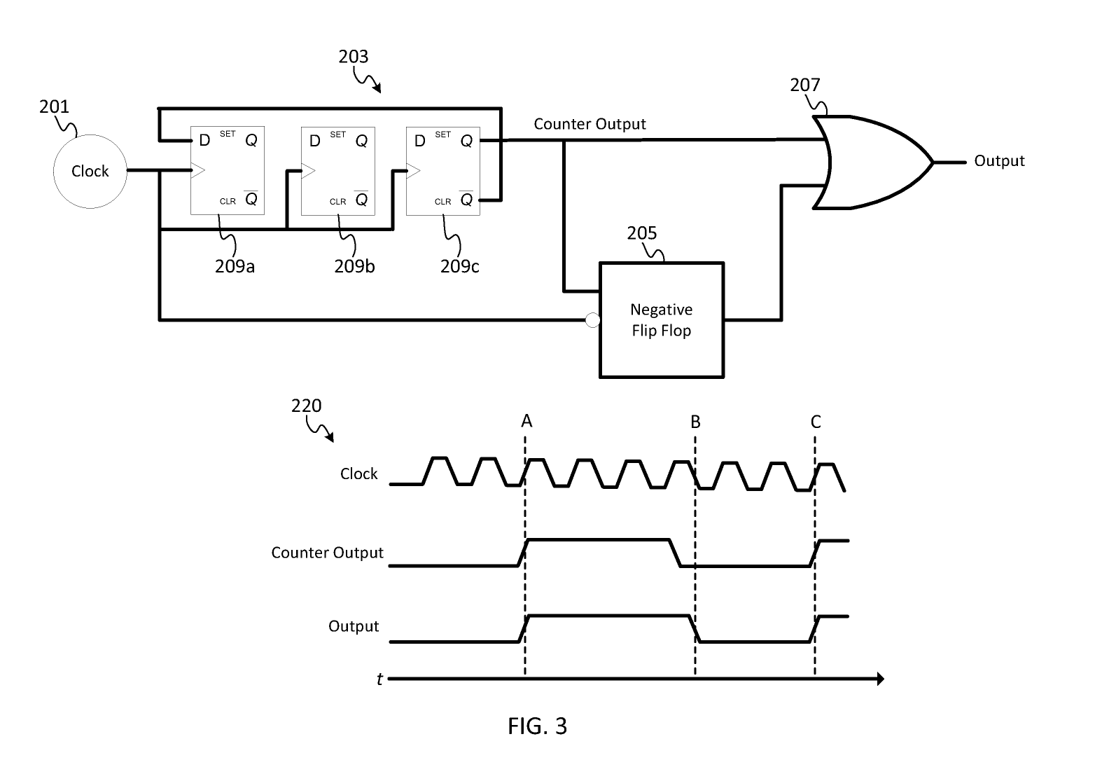

FIG. 3 illustrates another implementation of the clock divider circuit 100 of FIG. 1. The implementation of FIG. 3 includes a source clock signal 201, a counter 203, a negative flip-flop 205, and an OR gate 207. In other implementations, other logic may be used to perform similar functionality.

The counter 203 includes a plurality of flip-flops 209a-c. The flip-flops may be JK flip-flops, data or delay (D) flip-flops, toggle (T) flip-flops, or set-reset (SR) flip-flops. The negative flip-flop 205 may be referred to as a supplemental flip-flop to distinguish from flip-flops 209a-c.

The counter 103 may be a ring counter. A ring counter includes a circular shift register in which the output of the last stage of the shift register is fed to the input of the first stage of the shift register. The counter 103 may be a twisted ring counter that connects the complement of the output of the last stage of the shift register to the input of the first stage of the shift register, which circulates a series of ones followed by zeros around the counter 103.

The twisted ring counter includes an inverted feedback. An example twisted ring counter is a Johnson counter. The Johnson counter may be an N-stage counter within which a single data bit is circulated through a sequence of 2N states. The N-stage counter may also be referred to as a mod-2N counter. Table 1 illustrates an example counter sequence for a twisted ring counter with three stages and six states.

TABLE 1

| State | First Stage | Second Stage | Third Stage |
|---|---|---|---|
| 0 | 0 | 0 | 0 |
| 1 | 1 | 0 | 0 |
| 2 | 1 | 1 | 0 |
| 3 | 1 | 1 | 1 |
| 4 | 0 | 1 | 1 |
| 5 | 0 | 0 | 1 |

As illustrated by timing diagram 220, the frequency of the counter output is less than the frequency of the source clock. The rising edges of the counter input coincide with the rising edges of the source clock, as shown by the dotted line at time, t=A. The falling edges of the counter input do not coincide with the falling edges of the source clock, as shown by the dotted line at t=B. The output of the OR gate 207 has rising edges that coincide with the rising edges of the source clock, as shown by the dotted lines at t=A and t=C, and falling edges that coincide with the falling edges of the source clock, as shown by the dotted line at t=B.

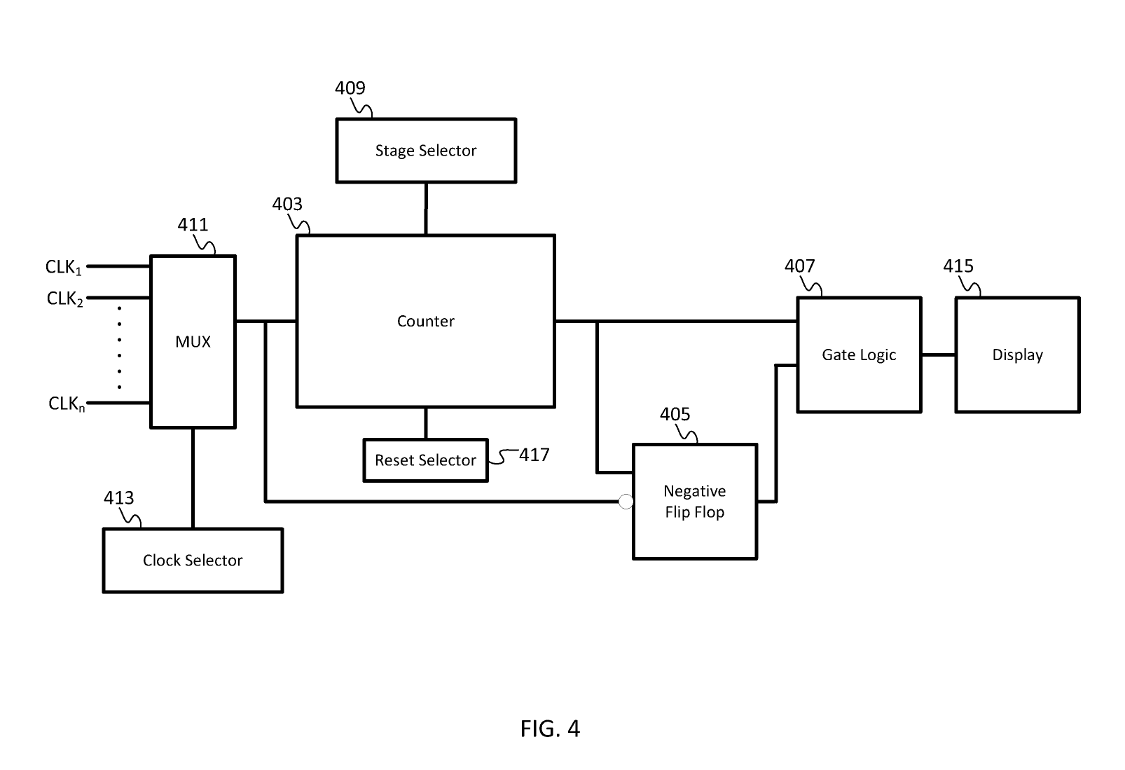

FIG. 4 illustrates another implementation of the clock divider circuit 100 of FIG. 1. The implementation of FIG. 4 includes an array of source clock signals CLK₁ through CLKₙ, a multiplexer 411, a counter 403, a negative flip-flop 405, a gate logic 407, a display 415, a stage selector 409, a clock selector 413, and a reset selector 417. In one implementation, the clock divider circuit of FIG. 4, including the multiplexer 411, the counter 403, the negative flip-flop 405, the gate logic 407, the stage selector 409, the clock selector 413, and the reset selector 417 may be implemented by a single controller (e.g., ASIC).

The array of source clock signals may be generated respectively by a group of integrated circuits. The integrated circuits may be the same or different types of circuits. For example, the group of integrated circuits may be randomly selected from a production line. The implementation of FIG. 4 is configured to quickly and individually test each of the group of integrated circuits.

The clock selector 413 includes a user input. The user input may include a dip switch, a key pad, or a touchscreen. The user input may be part of a workstation computer. The clock selector 413 generates a clock selection command, which is sent to the multiplexer 411. The multiplexer 411 is configured to select the source clock signal from the plurality of clock signals CLK₁ through CLKₙ based on the clock selection command. The number of clock signals, n, may be programmable or user selected.

Alternatively, the determination of n may be automatic, based on the number of clock signals detected at inputs of the multiplexer 411.

The stage selector 409 includes another user input, which may be one or more of a dip switch, a key pad, a touchscreen, or integrated with a workstation computer. The user input of the stage selector 409 and the user input of the clock selector 413 may be combined. The stage selector 409 is configured to generate a command signal defining a number of stages for the counter 403. The number of stages of the counter 403 may be any integer. The counter 403 has twice as many states as stages.

The reset selector 417 includes another user input, which may be a switch or button, or integrated with a workstation computer. The reset selector 417 may be combined with the state selector 409 or the clock selector 413 or both. The reset selector 417 is configured to generate an initialization signal. The initialization signal initializes the flip-flops or shift registers of the counter 403 to a predetermined state. For example, the reset selector 417 may be connected to the set input of each of a plurality of flip-flops of the counter 403. The predetermined state of the flip-flops or shift registers of the counter 403 may be initialized to the same state.

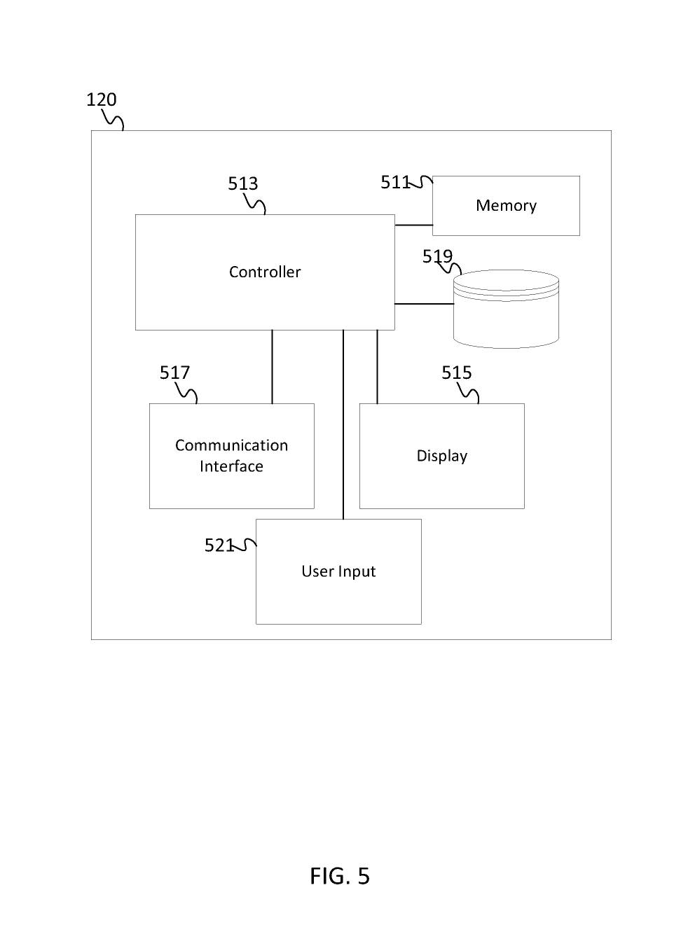

FIG. 5 illustrates an example of the test equipment 120 of FIG. 1. The test equipment 120 includes a memory 511, a controller 513, a display 515, a communication interface 517, a database 519, and a user input 521. The test equipment 120 may be integrated with the clock divider circuit 100. The test equipment 120 may be a handheld device, a laptop, or a personal computer.

The controller 513 is configured to receive the final clock signal from the clock divider circuit 100 and analyze the jitter from the falling edge of the source clock signal and/or the jitter from the rising edge of the source clock signal. The analysis may include a comparison the jitter from the falling edge of the source clock signal and/or the jitter from the rising edge of the source clock signal to a threshold. The controller 513 generates an error message if the falling edge of the source clock signal or the jitter from the rising edge of the source clock signal exceeds the threshold. The error message may include one or more of the amount of jitter and an identifier for the clock signal. The amount of jitter may be separated into an amount of jitter for the rising edge and an amount of jitter for the falling edge. The jitter may be frequency jitter or timing jitter. The error message may include a count value, indicating how many times jitter has occurred. The error message may include a repeating value, indicating how often the jitter occurs. The jitter may be as infrequent as one clock cycle with significant jitter every few hours.

The memory 511 may store the error message or data indicative of the amount of jitter. The memory 511 may be any known type of volatile memory or a non-volatile memory. The memory 511 may include one or more of a read only memory (ROM), dynamic random access memory (DRAM), a static random access memory (SRAM), a programmable read only memory (PROM), a flash memory, an electronic erasable program read only memory (EEPROM), random access memory (RAM), or other type of memory. The memory 511 may include an optical, magnetic (hard drive) or any other form of data storage device. The memory 511 may be located in a remote device or a removable device, such as a secure digital (SD) memory card.

The database 519 is configured to log the error messages over time. The error messages may be logged in connection with an identity of the source clock signal. The database 519 may be external to the test equipment 120. The database 519 may be replaced with removable storage media.

The display 515 may be configured to display an image indicative of the final clock signal. The image may be a waveform. The image may be a jitter value expressed in alphanumeric characters. The image may indicate whether the jitter value corresponds to the rising edge or the falling edge of the source clock signal. The image may include an identity of the source clock signal.

The display 515 may be a liquid crystal display (LCD) panel, light emitting diode (LED) screen, thin film transistor screen, or another type of display. The display 515 may be combined with the user input device 521 as a touch screen, which may capacitive or resistive. In addition, the user input device 521 may include one or more buttons, keypad, keyboard, mouse, stylist pen, trackball, rocker switch, touch pad, voice recognition circuit, or other device or component for inputting data to the test equipment 120. The user input device 521 may be combined with any combination of the stage selector 409, the reset selector 417, and the clock selector 413. The test equipment 120 may be configured to receive data from one or both of the stage selector 409 and the clock selector 413.

The memory 511 may store computer executable instructions for analyzing a divided clock signal. The controller 513 may execute computer executable instructions. The computer executable instructions may be included in computer code. The computer code may be written in any computer language, such as C, C++, C#, Java, Pascal, Visual Basic, Perl, HyperText Markup Language (HTML), JavaScript, assembly language, extensible markup language (XML) and any combination thereof.

The computer code may be stored in one or more tangible media or one or more non-transitory computer readable media for execution by the controller 513. A computer readable medium may include, but is not limited to, a floppy disk, a hard disk, an application specific integrated circuit (ASIC), a compact disk CD, other optical medium, a random access memory (RAM), a read only memory (ROM), a memory chip or card, a memory stick, and other media from which a computer, a processor or other electronic device can read.

The controller 513 may include a general processor, digital signal processor, application specific integrated circuit, field programmable gate array, analog circuit, digital circuit, server processor, combinations thereof, or other now known or later developed processor. The controller 513 may be a single device or combinations of devices, such as associated with a network or distributed processing. Any of various processing strategies may be used, such as multi-processing, multi-tasking, parallel processing, remote processing, centralized processing or the like. The controller 513 may be responsive to or operable to execute instructions stored as part of software, hardware, integrated circuits, firmware, micro-code or the like.

The communication interface 517 is in communication with the circuit divider circuit 100. The communication interface 517 may be in communication with the remote devices by way of the Internet. The communication interface 517 may include any operable connection. An operable connection may be one in which signals, physical communications, and/or logical communications may be sent and/or received. An operable connection may include a physical interface, an electrical interface, and/or a data interface. An operable connection may include differing combinations of interfaces and/or connections sufficient to allow operable control. For example, two entities can be operably connected to communicate signals to each other or through one or more intermediate entities (e.g., processor, operating system, logic, software). Logical and/or physical communication channels may be used to create an operable connection. As used herein, the phrases “in communication” and “coupled” are defined to mean directly connected to or indirectly connected through one or more intermediate components. Such intermediate components may include both hardware and software based components.

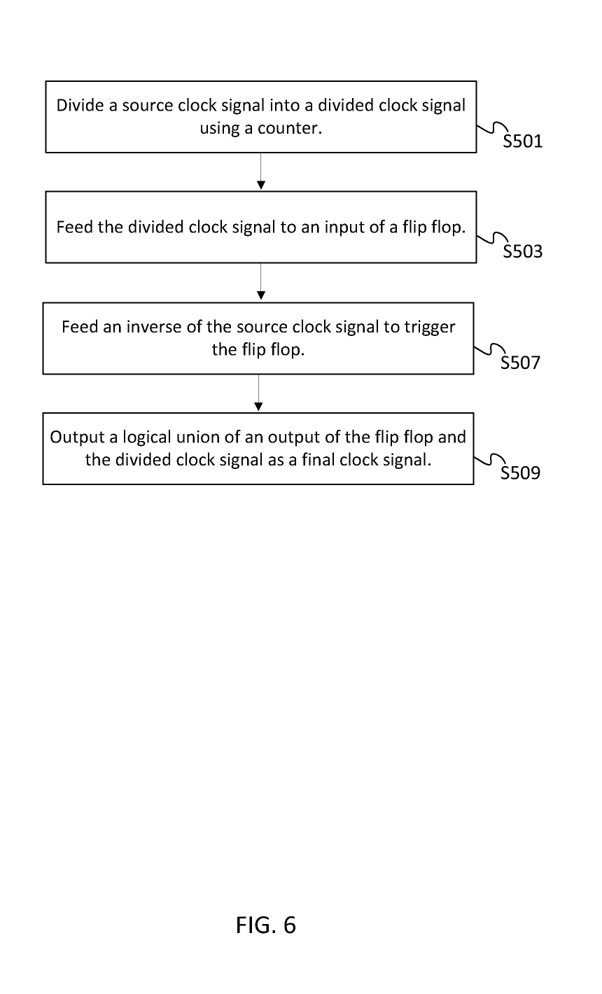

FIG. 6 illustrates an example flow chart for generating a clock that can be analyzed for jitter on both output edges. At act S501, a counter divides a source clock signal into a divided clock signal. The frequency of the divided clock signal is lower than a frequency of the source clock signal. The source clock signal may be generated at integrated circuit 110. The source clock signal may be at least 100 MHz. The counter may include any number of flip-flops or shift registers.

At S503, the counter outputs the divided clock signal, which is fed to an input of a two-state sequential logic device supplemental to the logic devices of the counter. The divided clock signal preserves jitter from the rising edge of the source clock.

At S507, the clock divider circuit feeds an inverse of the source clock signal to trigger the two-state sequential logic device. The two-state sequential logic device may be any type of flip-flop such as a JK flip-flop or a D flip-flop or any type of a latch such as a set-reset latch (SR latch, JK latch) or a gated latch. The two-state sequential logic device may include a negative input or inverting input for the inputted source clock signal. Alternatively, an independent inverter gate may be connected to the input to receive the source clock signal and output an inverted source clock signal. The inverted source clock signal preserves jitter from the falling edge of the source clock signal.

At S509, the clock divider circuit outputs a logical union of an output of the two-state sequential logic device and the divided clock signal as a final clock signal. The final clock signal includes the jitter from the falling edge of the source clock signal and/or the jitter from the rising edge of the source clock signal. The final clock signal may be transmitted to the test equipment. The test equipment displays an image or data indicative of the jitter from the falling edge of the source clock signal and/or the jitter from the rising edge of the source clock signal.

Various embodiments described herein can be used alone or in combination with one another. The foregoing detailed description has described only a few of the many possible implementations of the present embodiments. For this reason, this detailed description is intended by way of illustration, and not by way of limitation.

I claim:

1. A method comprising:
converting a source clock signal into a divided clock signal using a counter, wherein a frequency of the divided clock signal is lower than a frequency of the source clock signal;
feeding the divided clock signal to an input of a two-state sequential logic device, wherein the divided clock signal preserves jitter from a first edge of the source clock signal;
feeding an inverse of the source clock signal to trigger the two-state sequential logic device, wherein the inverse of the source clock signal preserves jitter from a second edge of the source clock signal; and
outputting a logical union or intersection of an output of the two-state sequential logic device and the divided clock signal as a final clock signal, wherein the final clock signal includes the jitter from a falling edge of the source clock signal and the jitter from a rising edge of the source clock signal.

2. The method of claim 1, further comprising:
analyzing at least one of the jitter from the falling edge of the source clock signal or the jitter from the rising edge of the source clock signal.

3. The method of claim 1, wherein the counter is a ring counter comprises a plurality of flip-flops and the two-state sequential logic device is a supplemental flip-flop.

4. The method of claim 3, wherein the ring counter is an N-bit Johnson counter.

5. The method of claim 1, further comprising:
initializing a plurality of flip-flops in the counter to predetermined states.

6. The method of claim 1, further comprising:
displaying an image indicative of the final clock signal.

7. The method of claim 1, further comprising:
comparing the jitter from the falling edge of the source clock signal and the jitter from the rising edge of the source clock signal to a threshold; and
generating an error message if the jitter from the falling edge of the source clock signal or the jitter from the rising edge of the source clock signal exceeds the threshold.

8. An apparatus comprising:
a counter configured to divide a source clock signal into a divided clock signal, wherein a frequency of the divided clock signal is lower than a frequency of the source clock signal;
a flip-flop configured to generate an output based on the divided clock signal and an inverse of the source clock signal; and
a logic gate configured to generate a final clock signal based on a logical union of the output of the flip-flop and the divided clock signal, wherein the final clock signal includes characteristics of a first edge of the source clock signal and characteristics of a second edge of the source clock signal.

9. The apparatus of claim 8, further comprising:
a controller configured to analyze at least one of the characteristics of the first edge of the source clock signal or the characteristics of the second edge of the source clock signal.

10. The apparatus of claim 9, wherein the controller is configured to compare jitter from the first edge of the source clock signal and jitter from the second edge of the source clock signal to a threshold jitter value and generate an error message if the jitter from the first edge of the source clock signal or the jitter from the second edge of the source clock signal exceeds the threshold jitter value.

11. The apparatus of claim 8, wherein the counter is a ring counter.

12. The apparatus of claim 11, wherein the ring counter is an N-bit Johnson counter.

13. The apparatus of claim 8, further comprising:
a stage selector configured to generate a command signal defining a number of stages of the counter.

14. The apparatus of claim 8, further comprising:
a multiplexer connected to the counter and configured to select the source clock signal from a plurality of clock signals.

15. The apparatus of claim 8, further comprising:
a display configured to graphically represent the final clock signal including the characteristics of the first edge of the source clock signal and the characteristics of the second edge of the source clock signal.

16. The apparatus of claim 8, wherein the logic gate configured to generate the logical union of the output of the flip-flop and the divided clock signal is an OR gate.

17. A non-transitory computer readable medium storing instructions that, when executed, are configured to cause a controller to:
divide a source clock signal into a divided clock signal using a ring counter, wherein a frequency of the divided clock signal is lower than a frequency of the source clock signal;
feed the divided clock signal to an input of a flip-flop, wherein the divided clock signal preserves jitter from a rising edge of the source clock;
feed an inverse of the source clock signal to trigger the flip-flop, wherein the inverse of the source clock signal preserves jitter from a falling edge of the source clock signal; and
output a logical union of an output of the flip-flop and the divided clock signal as a final clock signal, wherein the final clock signal includes the jitter from the falling edge of the source clock signal and the jitter from the rising edge of the source clock signal.

18. The non-transitory computer readable medium of claim 17, including instructions configured to cause a controller to:
analyze at least one of the jitter from the falling edge of the source clock signal or the jitter from the rising edge of the source clock signal.

19. The non-transitory computer readable medium of claim 17, wherein the ring counter is an N-bit Johnson counter having a plurality of flip-flops.

20. The non-transitory computer readable medium of claim 19, including instructions configured to cause a controller to:
receive an initialization signal to set the plurality of flip-flops to a common state.
